(19) United States
(12) Patent Application Publication
(10) Pub. No.: US 2019/0196626 A1
(43) Pub. Date: Jun. 27, 2019

(54) OPERATION INPUT DEVICE

(71) Applicant: KABUSHIKI KAISHA TOKAI RIKA DENKI SEISAKUSHO, Aichi (JP)

(72) Inventors: Masahiro TAKAHASHI, Aichi (JP); Ryoko NAKANO, Aichi (JP)

(21) Appl. No.: 16/322,237

(22) PCT Filed: Jun. 15, 2017
(86) PCT No.: PCT/JP2017/022175

§ 371 Date: Jan. 31, 2019

(30) Foreign Application Priority Data
Aug. 8, 2016 (JP) 2016-155408

(51) Int. Cl. G06F 3/044; G06F 3/041; H03K 17/96; B60K 35/00

(52) U.S. Cl. CPC G06F 3/044; B60K 35/00; H03K 17/962; G06F 3/0414

(57) ABSTRACT

An operation input device includes a capacitance sensor including detection regions in a matrix where detectors are disposed in a matrix, a pressure sensor disposed so as to overlap with the capacitance sensor, an operation detector formed by disposing the capacitance sensor and the pressure sensor so as to overlap with a base part, and a controller configured to detect capacitance information and pressure information from the capacitance sensor and the pressure sensor and to detect an operation state to the operation detector in a matrix.

### TECHNICAL FIELD

The present invention relates to an operation input device.

### BACKGROUND ART

There has been known an operation input device that estimates further accurately a distance between a capacitance sensor and driver's fingertips (e.g., see Patent Document 1). The operation input device is configured to include a capacitance sensor including a plurality of first conductors disposed side by side in a front-rear direction of a vehicle, and a controller that estimates a spaced distance between the capacitance sensor and driver's fingers based on an amount of electric charges stored in the first conductor disposed on a rear side of the vehicle among the plurality of first conductors; and then estimates a front-rear position of the driver's fingers on the capacitance sensor based on a difference between the amounts of electric charges stored in the plurality of respective first conductors.

This operation input device estimates the distance between the capacitance sensor and driver's fingertips; estimates a right-left position of the finger based on which region of a second conductor the electric charges are unevenly stored in; and estimates the spaced distance between the finger and the capacitance sensor based on the amount of electric charges stored in an edge region on the front side of the capacitance sensor, thus it is possible to detect movement of the finger more accurately and estimate an upper-lower position or a right-left position of the finger.

### CITATION LIST

### Patent Document

### Patent Document 1: JP 2016-9301 A

### SUMMARY OF INVENTION

### Technical Problem

However, the operation input device disclosed in Patent Document 1 can estimate an upper-lower position or a right-left position of operator's fingertips, but cannot determine whether the hand is the right hand or the left hand and also cannot detect a state of the palm made to come into contact with an operation surface. In other words, the operation input device in the related art cannot detect operator's fingers in a matrix with respect to an operation input part, thus there has been a problem that it is not possible to detect various types of operation input information such as a contact position with respect to the operation input part, contact pressure (pressing force), an area with which the hands come into contact, a distance away from (close to) fingers, and the like.

The invention aims to provide an operation input device capable of detecting various types of operation input information in a matrix, such as a contact position with respect to an operation input part, contact pressure (pressing force), an area with which the hands come into contact, a distance away from (close to) fingers, and the like.

### Solution to Problem

(1) An operation input device according to an embodiment of the invention includes a capacitance sensor configured to dispose detectors in a matrix and have detection regions in a matrix; a pressure sensor disposed to be overlapped with the capacitance sensor; an operation detector composed of the capacitance sensor and the pressure sensor that are disposed to be overlapped with a base part; and a controller configured to detect capacitance information and pressure information from the capacitance sensor and the pressure sensor and to detect an operation state for the operation detector in a matrix.

(2) In the operation input device described in (1), the capacitance sensor may be formed by arranging a plurality of strip capacitance sensors in a matrix, the strip capacitance sensor being composed of the detectors that are disposed in a row.

(3) In the operation input device described in (1) or (2), the base part may be formed in a grip shape, a flat shape, a quadratic curved shape, or a 3-dimensional curved shape.

(4) In the operation input device described in (1) or (2), the controller may be configured to generate the capacitance information obtained by a combination of coordinate values indicating a position of the detector defined by straight lines extending in first and second arrangement directions of the detector and capacitance signal values detected by the detector.

(5) In the operation input device described in (4), the controller may be configured to detect a grip position of the capacitance sensor gripped by fingers by calculating the center of gravity in a detection region of the capacitance sensor from the distribution of the capacitance signal values based on the capacitance information.

(6) In the operation input device described in (1) or (4), the controller may be configured to detect a state of the palm which comes into contact with the capacitance sensor and a force adjustment by hand, or a hover state of fingers from the pressure information and the distribution of the capacitance signal values.

### Advantageous Effects of Invention

According to an embodiment of the invention, an operation input device capable of detecting various types of operation input information in a matrix, such as a contact position with respect to an operation input part, contact pressure (pressing force), an area with which the hands come into contact, a distance away from (close to) fingers, and the like can be provided.

### BRIEF DESCRIPTION OF DRAWINGS

FIG. 1A is a cross-sectional view of an operation input device according to an embodiment.

FIG. 1B is a plan view when viewed from a side for operation.

FIG. 2 is an explanatory view of a steering of a vehicle including a capacitance built-in grip having a capacitance sensor.

FIG. 3A is a perspective view of a state in which an operator grips the capacitance built-in grip.

FIG. 3B is a cross-sectional view of FIG. 3A.

FIG. 3C is an explanatory view illustrating a state in which the operator is in a state of gripping the capacitance built-in grip to stretch fingers other than thumb.

FIG. 3D is an explanatory view illustrating a state in which the operator is in a state of gripping the capacitance built-in grip to repeat a state of stretching fingers illustrated in FIG. 3C and a gripping state.

FIG. 4A is an explanatory view illustrating capacitance signal values of the capacitance sensor in a matrix in a state in which the operator grips the capacitance built-in grip illustrated in FIG. 3A.

FIG. 4B is an explanatory view illustrating capacitance signal values of the capacitance sensor in a matrix in a state in which the operator grips the capacitance built-in grip illustrated in FIG. 3C.

FIG. 5A is a perspective view illustrating an arrangement state of the capacitance sensor (strip capacitance sensor) in a case that a base part is formed in a flat shape.

FIG. 5B is a perspective view illustrating an arrangement state of the capacitance sensor (strip capacitance sensor) in a case that the base part is formed in a quadratic curved shape.

FIG. 5C is a perspective view illustrating an arrangement state of the capacitance sensor (strip capacitance sensor) in a case that the base part is formed in a 3-dimensional curved shape.

### DESCRIPTION OF EMBODIMENT

### Embodiments of Present Invention

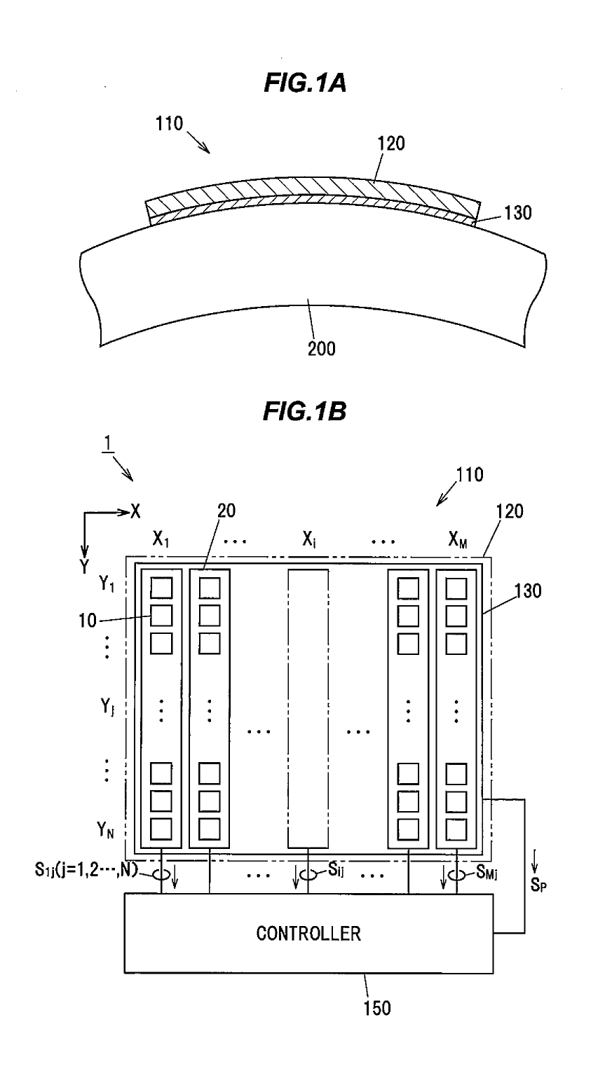

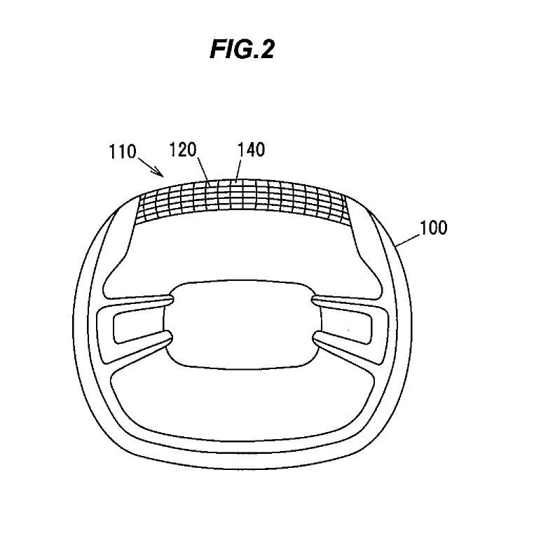

FIG. 1A is a cross-sectional view of an operation input device according to an embodiment, and FIG. 1B is a plan view as being extended to a plane when viewed from a side for operation in FIG. 1A. FIG. 2 is an explanatory view of a steering of a vehicle including a capacitance built-in grip having a capacitance sensor.

An operation input device 1 includes a capacitance sensor 120 configured to dispose detectors 10 in a matrix and have detection regions in a matrix, a pressure sensor 130 disposed to be overlapped with the capacitance sensor 120, an operation input sensor 110 as an operation detector composed of the capacitance sensor 120 and the pressure sensor 130 that are disposed to be overlapped with a base part 200, and a controller 150 configured to detect capacitance information Sij (i=1, . . . , M, j=1, . . . , N) and pressure information SP from the capacitance sensor 120 and the pressure sensor 130 and to detect an operation state for the operation input sensor 110 in a matrix.

This operation input device 1 is configured to detect a state of fingers in contact or in proximity (a contact position, a state of palm made to contact and a force adjustment by hand, the determination of the right and left hands, a hover state of fingers, and the like) by using the capacitance sensor 120 including detectors in a matrix disposed on the base part 200 having a given shape and the pressure sensor 130 disposed to be overlapped with the capacitance sensor 120.

As illustrated in FIG. 1A, the capacitance sensor 120 and the pressure sensor 130 are disposed to be overlapped with the base part 200 having a surface formed in a given shape to configure the operation input sensor 110. The surface shape of the base part 200 is applicable to a flat shape, a quadratic curved shape, a 3-dimensional curved shape, or the like in addition to a grip shape as illustrated in FIG. 2.

FIG. 1B is a plan view illustrating as being extended to a plane when viewed from a side for operation in FIG. 1A. The capacitor sensor 120 is configured to dispose the detectors 10 in a matrix and have the detection regions in a matrix. As illustrated in FIG. 1B, the detectors 10 as an electrostatic touch electrode are disposed in a row to form a strip capacitance sensor 20, and a plurality of strip capacitance sensors 20 are arranged in a matrix to thereby configure the capacitor sensor 120 in a matrix.

Examples of available methods for arranging the plurality of strip capacitance sensors 20 include arranging each of the strip capacitance sensors 20 at regular intervals without a space or with a predetermined space, arranging each of the strip capacitance sensors 20 at irregular intervals, and the like. Especially, in a case that the surface shape of the base part 200 is a 3-dimensional curved shape or the like, each of the strip capacitance sensors 20 can be disposed in a matrix at regular or irregular intervals, with a space or not, and the like in combination, in accordance with the surface shape of a position of placement.

Each of the strip capacitance sensors 20 outputs capacitance information Sij (i=1, . . . , M, j=1, . . . , N) to the controller.

The pressure sensor 130 outputs the pressure information SP to the controller. Note that, the pressure sensor 130 detects whether the base part 200 is contacted; and contact strength (pressure) regardless of the contact position.

As illustrated in FIG. 1B, the capacitance sensor 120 is configured such that M-pieces of strip capacitance sensors 20 are arranged and then the detectors 10 as an electrostatic touch electrode are formed in a matrix. In other words, the detectors 10 of X1 to XM are formed in an X direction, and the detectors 10 of Y1 to YM are formed in a Y direction.

As illustrated in FIG. 2, the operation input device 1 according to the embodiment is configured such that the operation input sensor 110 is mounted on the capacitance built-in grip 140. The capacitance built-in grip 140 is provided on a steering 100 of a vehicle at an upper part thereof, for example.

### Strip Capacitance Sensor 20, Capacitance Sensor 120

As illustrated in FIG. 1B, the strip capacitance sensor 20 is a capacitance sensor in which the detectors 10 as the electrostatic touch electrode are disposed in a row and then to be formed in a strip shape. The detectors 10 constitute a self-capacitance sensor in which an electric current is supplied in a predetermined cycle to detect capacitance between the sensor and fingers in contact or in proximity.

The respective detectors 10 are electrically connected so as to output respective detection capacitance values (parasitic capacitance value) to the controller 150. Note that, detection processing for the detection capacitance values (parasitic capacitance value) of respective detectors 10 can be performed while being sequentially switched in the controller 150.

In the capacitance sensor 120, as illustrated in FIG. 1B, operation input coordinates (X, Y) in which an X-axis is rightward and a Y-axis is downward from an upper left part defined as a coordinate origin are set. The controller 150 periodically switches connection to the capacitance sensor 120 and reads out the capacitance of each of the detectors 10. The controller 150 generates the capacitance information Sij (i=1, . . . , M, j=1, . . . , N) as a capacitance count value obtained by performing analog-digital conversion processing or the like with respect to the read-out capacitance, as an example.

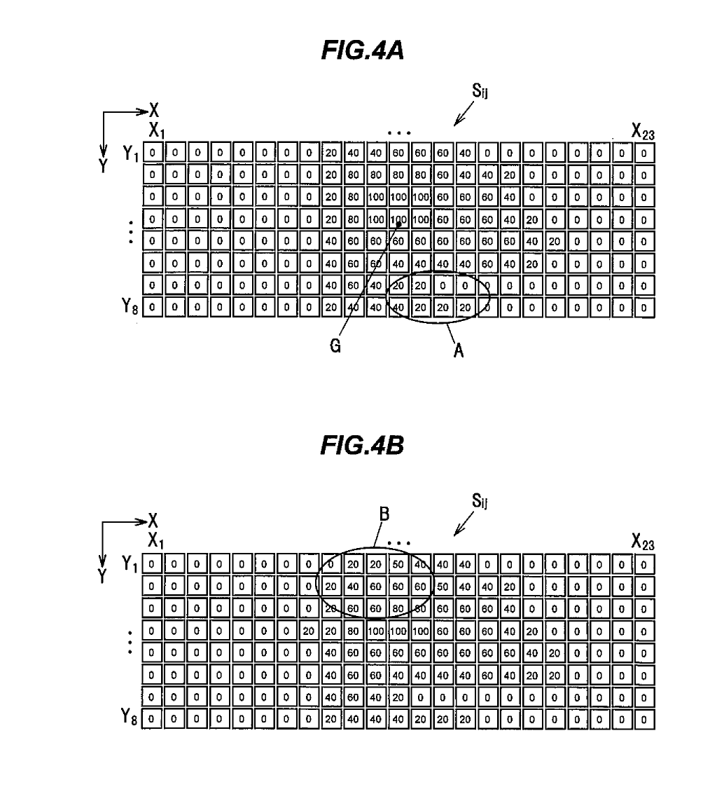

The capacitance information Sij (i=1, . . . , M, j=1, . . . , N) is generated depending on a set resolution. In the embodiment, as illustrated in FIG. 4 described later, processing is performed in a manner such that the capacitance information Sij can be obtained from a combination of a coordinate X1 to a coordinate X23, a coordinate Y1 to a coordinate Y8, and the capacitance count value.

### Pressure Sensor 130

The pressure sensor 130 is formed in a sheet shape; and detects whether there is a touched and touch strength (pressure). The sheet-shaped pressure sensor 130 disposes, for example, electrode sheets as a sensor cell between resin sheets; and detects electric resistance values due to a load. The controller 150 performs the analog-digital conversion processing or the like with respect to the detected electric resistance value and generates the pressure information SP as a pressure count value.

### Configuration of Controller 150

For example, the controller 150 is a microcomputer including a Central Processing Unit (CPU) that computes and processes acquired data according to stored programs; and Random Access Memory (RAM) and Read Only Memory (ROM) that are semiconductor memory. A program for operations of the controller 150, for example, is stored in the ROM. The RAM is used as a storage region that temporarily stores computation results and the like, for example; and the capacitance information Sij, the pressure information SP, and the like are generated.

### EXAMPLES

As an example, it is described that the operation input sensor 110 (capacitance sensor 120) including the detectors 10 in a matrix of 23×8 is mounted on the capacitance built-in grip illustrated in FIG. 2. In other words, in FIG. 1B, supposing, the operation input sensor 110 (capacitance sensor 120) is defined as follows: M=23 and N=8.

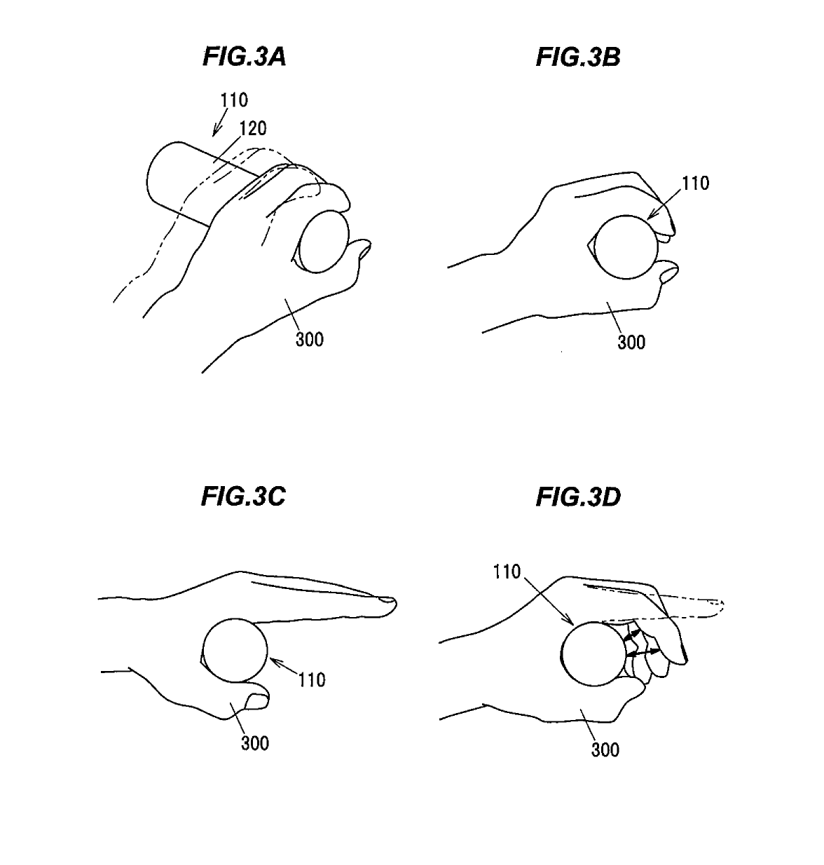

FIG. 3A is a perspective view of a state in which an operator grips the capacitance built-in grip, FIG. 3B is a cross-sectional view of FIG. 3A, FIG. 3C is an explanatory view illustrating a state in which the operator is in a state of gripping the capacitance built-in grip to stretch fingers other than thumb, and FIG. 3D is an explanatory view illustrating a state in which the operator is in a state of gripping the capacitance built-in grip to repeat a state of stretching fingers illustrated in FIG. 3C and a gripping state. FIG. 4A is an explanatory view illustrating capacitance signal values of the capacitance sensor in a matrix in a state in which the operator grips the capacitance built-in grip illustrated in FIG. 3A, and FIG. 4B is an explanatory view illustrating capacitance signal values of the capacitance sensor in a matrix in a state in which the operator grips the capacitance built-in grip illustrated in FIG. 3C.

### Detection of Grip Position

In a case that a distribution diagram of the capacitance signal values can be obtained from the capacitance information Sij in FIG. 4A from the gripping state in FIG. 3A, the center of gravity G can be calculated as the grip position of fingers 300. An X-coordinate of a position of the center of gravity G is an average value of numerical values in FIG. 4A. The average value can be calculated by dividing the sum of values of the X-coordinate of each detector with the number of detectors in which the numerical values are present. Likewise, a Y-coordinate of the position of the center of gravity G is an average value of numerical values in FIG. 4A. The average value can be calculated by dividing the sum of values of the Y-coordinate of each detector with the number of detectors in which the numerical values are present. As illustrated in FIG. 4A, the center of gravity G (X, Y) can be calculated by performing a center-of-gravity calculation described above defining that X is rightward and Y is downward from an upper left part as the coordinate origin. Note that, binarization is applied to a touch region where the detected value exceeds a certain threshold as a contact region, therefore, it is also possible to calculate the position of the center of gravity G based on the binary distribution diagram.

### Determination of Right and Left Hands

In a case that the distribution diagram of the capacitance signal values can be obtained from the capacitance information Sij in FIG. 4A from the gripping state in FIG. 3A, it is possible to determine whether the hand of fingers 300 is the right hand or the left hand. For example, in FIG. 4A, binarization processing is performed to a region where the capacitance signal value is equal to or larger than 20 and a region where the capacitance signal value is below 20. Based on the distribution diagram obtained by binarization, using a pattern matching method which is a known technique, a position of thumb indicated in an A region in FIG. 4A is detected, which enables the determination of whether the hand of fingers 300 for grip is the right hand or the left hand. In order to make the determination more accurate, various types of templates for pattern matching are stored in a memory. The various types of templates are prepared for the right hand, the left hand, a state of gripping with index finger stretched, and a state of gripping with four fingers stretched. Besides, by performing calibration on such as a hand width for each operator, it is possible to accurately detect a positional relationship of the hand and the movement of the fingers.

### Detection of State of Palm Made to Contact and Force Adjustment by Hand

In a case that a distribution diagram of the capacitance signal values can be obtained from the capacitance information Sij in FIG. 4A from the gripping state in FIG. 3A, it is possible to detect a state of the palm made to contact and a force adjustment by hand. In a case that the contact is determined from the pressure information SP of the pressure sensor 130, the distribution diagram in FIG. 4A indicates the detection of a force adjustment by hand. Further, by setting the threshold, it is possible to detect a range of the palm and an area with which the hands come into contact and also possible to detect the force adjustment by hand in the range.

In addition, in a case that the states in FIG. 3C and FIG. 3D are repeated, the distribution diagrams of the capacitance signal values in FIG. 4A and FIG. 4B are repeatedly detected. In the distribution diagram of the capacitance signal values in FIG. 4B, values indicated in a B region in FIG. 4B are reduced in comparison with FIG. 4A. In order to detect such phenomenon, a distribution diagram for difference values is obtained based on the distribution diagrams of the capacitance signal values in FIG. 4A and FIG. 4B, whereby it is possible to determine whether and which finger is separated, and the like. In the example in FIG. 4B, it is possible to determine that four fingers other than thumb are repeatedly stretched as illustrated in FIG. 3C and FIG. 3D.

### Detection of Hover State of Fingers

The above describes a case that the fingers 300 are determined to be in contact state from the pressure information SP of the pressure sensor 130, but in a case that the fingers 300 are in a non-contact state from the pressure information SP of the pressure sensor 130, it is possible to determine that the fingers are in a hover state and close to the capacitance sensor 120. Also, in the hover state of the fingers, the detection of the position of the center of gravity, determination of the right and left hands, and the like described above are possible.

### Application Example to Various Shapes of Base Part

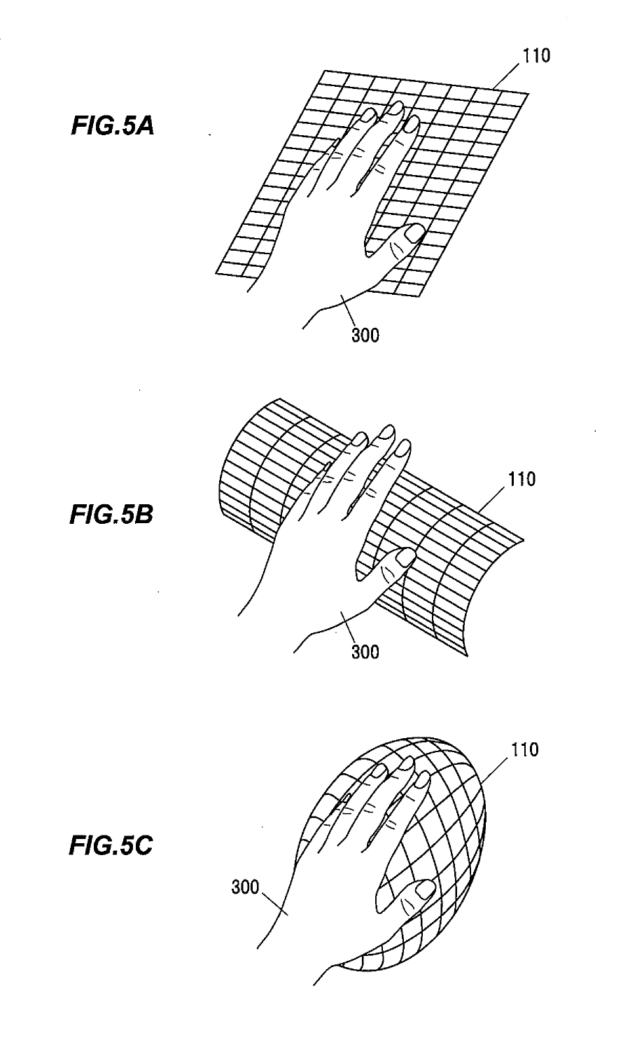

FIG. 5A is a perspective view illustrating an arrangement state of the capacitance sensor (strip capacitance sensor) in a case that the base part is formed in a flat shape, FIG. 5B is a perspective view illustrating an arrangement state of the capacitance sensor (strip capacitance sensor) in a case that the base part is formed in a quadratic curved shape, and FIG. 5C is a perspective view illustrating an arrangement state of the capacitance sensor (strip capacitance sensor) in a case that the base part is formed in a 3-dimensional curved shape.

As illustrated in FIG. 5A, when the operation input device 1 (operation input sensor 110) according to the embodiment is applied to the case that the base part is formed in a flat shape, the state of the palm can be detected. In addition, in a case that the fingers 300 are determined to be in a non-contact state from the pressure information SP of the pressure sensor 130, it is possible to detect a distance between the fingers 300 and the operation input sensor 110.

As illustrated in FIG. 5B, when the operation input device 1 (operation input sensor 110) according to the embodiment is applied to the case that the base part is formed in a quadratic curved shape, it is possible to detect whether the hand is the right hand or the left hand using the positional relationship between thumb and index finger, for example. In addition, it is also possible to detect operations such as grasping or twisting movement by the fingers 300.

As illustrated in FIG. 5C, when the operation input device 1 (operation input sensor 110) according to the embodiment is applied to the case that the base part is formed in a 3-dimensional curved shape, it is possible to perform various types of detection described above by disposing the plurality of strip capacitance sensors 20 even in a case of complicated shape.

### Effect of Embodiment of Present Invention

According to the embodiment, effects such as those described below are achieved.

(1) The operation input device 1 according to the embodiment is configured to include the capacitance sensor 120 disposing the detectors 10 in a matrix to have detection regions in a matrix; the pressure sensor 130 disposed to be overlapped with the capacitance sensor 120; the operation input sensor 110 as an operation detector composed of the capacitance sensor 120 and the pressure sensor 130 that are disposed to be overlapped with the base part 200; and the controller 150 that detects the capacitance information Sij (i=1, . . . , M, j=1, . . . , N) and the pressure information SP from the capacitance sensor 120 and the pressure sensor 130 and detects an operation state for the operation input sensor 110 in a matrix. Therefore, it is possible to detect states of fingers in contact or in proximity (a contact position, state of the palm made to contact and force adjustment by hand, determination of the right and left hands, hover state of fingers, and the like).

(2) The capacitance sensor 120 is configured by the method of arranging the plurality of strip capacitance sensors 20, so that the surface shape of the base part for placement is applicable to a flat shape, a quadratic curved shape, a 3-dimensional curved shape, or the like in addition to a grip shape illustrated in FIG. 2. Especially, the strip capacitance sensor 20 enables to achieve various arrangements and arrangement methods. The surface shape of the base part 200 corresponds to a flat shape, a quadratic curved shape, a 3-dimensional curved shape in addition to a grip shape, thus each of the strip capacitance sensors 20 can be disposed in a matrix at regular or irregular intervals, with a space or not, or the like, in combination.

(3) Owing to these effects, an operation input device capable of detecting various types of operation input information in a matrix, such as a contact position with respect to the operation input part, contact pressure (pressing force), an area with which the hands come into contact, a distance away from (close to) fingers, and the like can be provided.

Although several embodiments of the present invention have been described above, these embodiments are merely examples and the invention according to the claims is not to be limited thereto. These novel embodiments may be implemented in various other forms, and various omissions, substitutions, changes, and the like can be made without departing from the spirit and scope of the invention. In addition, all the combinations of the features described in these embodiments are not necessarily needed to solve the technical problem. Further, these embodiments are included within the spirit and scope of the invention and also within the invention described in the claims and the scope of equivalents thereof.

### REFERENCE SIGNS LIST

1 Operation input device
10 Detector
20 Strip capacitance sensor
120 Capacitance sensor
130 Pressure sensor
150 Controller
200 Base part
300 Finger

1. An operation input device comprising:
a capacitance sensor comprising detection regions in a matrix where detectors are disposed in a matrix;
a pressure sensor disposed so as to overlap with the capacitance sensor;
an operation detector formed by disposing the capacitance sensor and the pressure sensor so as to overlap with a base part; and
a controller configured to detect capacitance information and pressure information from the capacitance sensor and the pressure sensor and to detect an operation state to the operation detector in a matrix.

2. The operation input device according to claim 1, wherein the capacitance sensor is formed by arranging a plurality of strip capacitance sensors on the base part in a matrix, the strip capacitance sensor comprising the detectors arranged in a row.

3. The operation input device according to claim 1, wherein the base part is formed into a grip shape, a flat shape, a quadratic curved shape, or a 3-dimensional curved shape.

4. The operation input device according to claim 1, wherein the controller is configured to generate the capacitance information obtained by a combination of coordinate values indicating a position of the detectors defined by straight lines extending in first and second arrangement directions of the detectors and capacitance signal values detected by the detectors.

5. The operation input device according to claim 4, wherein the controller is configured to detect a grip position of the capacitance sensor by fingers by calculating a center of gravity in the detection regions of the capacitance sensor from a distribution of the capacitance signal values based on the capacitance information.

6. The operation input device according to claim 1, wherein the controller is configured to detect a state or a force adjustment of a palm which comes into contact with the capacitance sensor, or a hover state of fingers from the pressure information and a distribution of the capacitance signal values.
